(19) United States
(12) Patent Application Publication
(10) Pub. No.: US 2026/0371635 A1
(43) Pub. Date: Nov. 19, 2026

(54) METHOD AND DEVICE TO INCREASE NANOSHEET DEVICE WIDTH

(71) Applicant: Taiwan Semiconductor Manufacturing Co., Ltd., Hsinchu (TW)

(72) Inventors: Guan-Lin CHEN, Hsinchu (TW); Kuo-Cheng CHIANG, Hsinchu (TW); Shi Ning JU, Hsinchu (TW); Jung-Chien CHENG, Hsinchu (TW); Chih-Hao WANG, Hsinchu (TW)

(73) Assignee: Taiwan Semiconductor Manufacturing Co., Ltd., Hsinchu (TW)

(21) Appl. No.: 19/755,295

(22) Filed: Jul. 27, 2026

Related U.S. Application Data
(63) Continuation of application No. 18/744,471, filed on Jun. 14, 2024.
(60) Provisional application No. 63/551,465, filed on Feb. 8, 2024.

(51) Int. Cl. H10D 30/43; H10D 30/01; H10D 30/67; H10D 62/10; H10D 62/17; H10D 64/23; H10P 50/00

(52) U.S. Cl. CPC H10D 30/43; H10D 30/014; H10D 30/6735; H10D 30/6757; H10D 62/121; H10D 62/235; H10P 50/691; H10D 64/258

(57) ABSTRACT

A transistor includes a plurality of stacked channels. The stacked channels are initially patterned in accordance with a hard mask structure positioned above the stacked channels. Source/drain regions are then formed via a first epitaxial growth process such that the stacked channels extend in a first lateral direction between the source/drain regions. A second epitaxial growth process is then performed to increase the effective width of the channels by forming epitaxial semiconductor layers on side surfaces of the channels. After formation of the epitaxial semiconductor layers, the width of the channels in a second lateral direction transverse to the first lateral direction is greater than a width of the hard mask structure.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-11B are cross-sectional views and top views of an integrated circuit at various stages of processing, in accordance with some embodiments.

FIG. 12 is a sectional top view of a channel of a gate all around transistor, in accordance with some embodiments.

FIG. 13 is a top sectional view of a channel of a gate all around transistor, in accordance with some embodiments.

FIG. 14 is a side sectional view of a channel of the gate all around transistor, in accordance with some embodiments.

FIG. 15 is a side sectional view of a channel of the gate all around transistor, in accordance with some embodiments.

FIG. 16 is a side sectional view of a channel of the gate all around transistor, in accordance with some embodiments.

FIG. 17 is a side sectional view of an integrated circuit including a gate all around transistor, in accordance with some embodiments.

FIG. 18 is a flow diagram of a method for forming an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

Embodiments of the disclosure provide a gate all around transistor including a plurality of stacked channels. Embodiments of the present disclosure utilize a hard mask structure to assist in patterning the channels from a plurality of semiconductor layers. After formation of source/drain regions of the transistor, an epitaxial growth process is performed to effectively increase the channel width of each of the channels by forming an epitaxial semiconductor layer on the exposed side surfaces of the channels. Prior to the epitaxial growth process, the channels may have a width that is slightly smaller than a width of the hard mask structure. After the epitaxial growth process, the channels may have a width that is larger than the width of the hard mask structure. The result is a transistor with increased effective channel width. This results in increased currents in the on state of the transistor in the overall better performance of the transistor and electronic devices that incorporate the integrated circuit in which the transistor is formed.

The transistors may be termed “nanostructure transistors” and the channels may be termed “semiconductor nanostructures”. The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

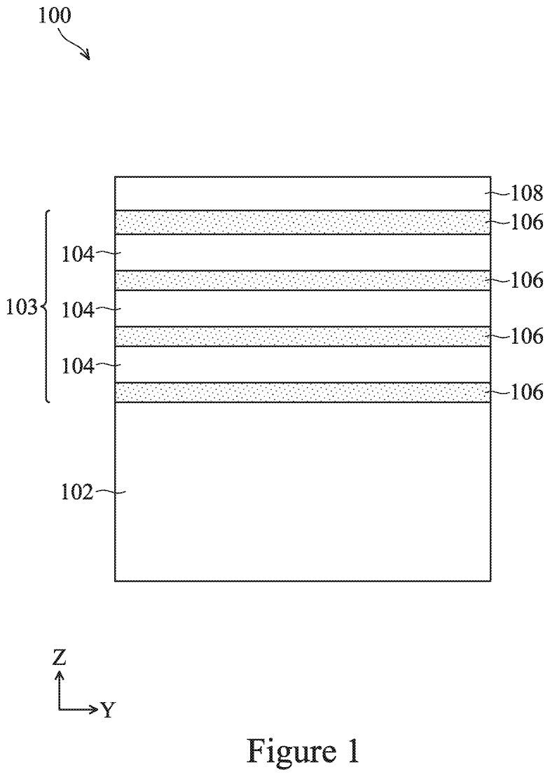

FIGS. 1-11B are cross-sectional top and side views of a portion of an integrated circuit 100 fabricated according to some embodiments of the present disclosure. The fabrication process results in a plurality of transistors 101, as will be described in further detail below.

FIG. 1 is a perspective view of the integrated circuit 100 at an intermediate state of processing. The integrated circuit 100 includes a substrate 102. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures. In FIG. 1, Three semiconductor layers 104 and four sacrificial semiconductor layers 106 are illustrated. In some embodiments, the multi-layer stack 103 may include fewer or more layers than are shown in FIG. 1.

In some embodiments, the semiconductor layers 104 may be formed of a first semiconductor material suitable for n-type semiconductor nanostructure transistors, such as silicon, silicon carbide, or the like, and the sacrificial semiconductor layers 106 may be formed of a second semiconductor material suitable for p-type semiconductor nanostructure transistors, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

As shown in FIG. 1, the integrated circuit 100 includes a hard mask layer 108 formed over the top sacrificial semiconductor layer 106. In some embodiments, the hard mask layer 108 includes a dielectric material. The dielectric material can include SiN, SiCN, SiOCN, SiOC, or other suitable dielectric materials. The hard mask layer 108 can have a thickness between 3 nm and 20 nm. Other materials and thicknesses may be utilized for the hard mask layer 108 without departing from the scope of the present disclosure.

Due to high etch selectivity between the materials of the semiconductor layers 104 and the sacrificial semiconductor layers 106, the sacrificial semiconductor layers 106 of the second semiconductor material may be removed without significantly removing the semiconductor layers 104 of the first semiconductor material, thereby allowing the semiconductor layers 104 to be released to form stacked channel regions of transistors.

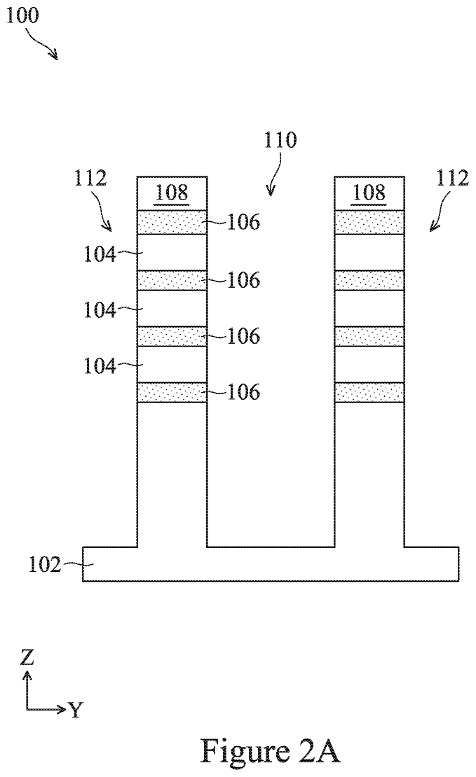

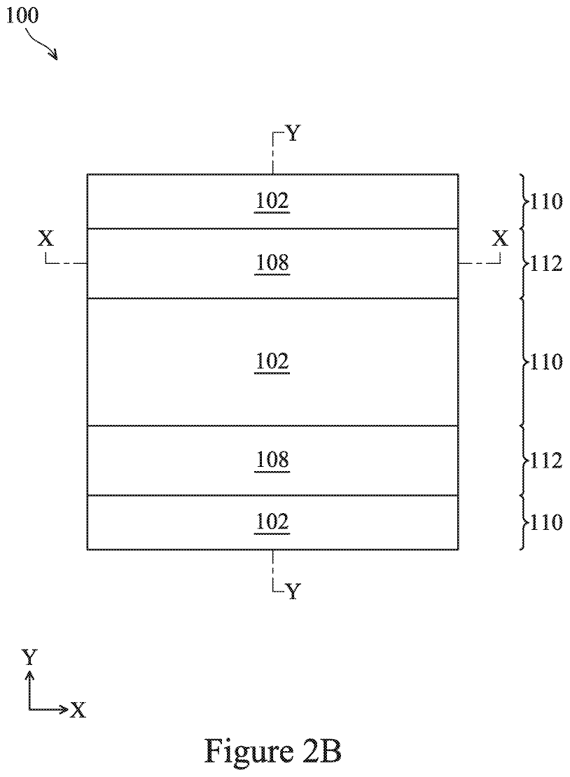

In FIG. 2A, the hard mask layer 108 has been patterned in accordance with a photolithography process. After patterning of the hard mask layer 108, trenches 110 have been formed in the stack 103 and in the substrate 102. The trenches 110 can be formed with an anisotropic etching process that etches in the downward direction. The etching process defines semiconductor fins 112 by forming trenches 110 through the hard mask layer 108, the dielectric layer 110, the sacrificial semiconductor layer 114, the sacrificial semiconductor layers 106, the semiconductor layers 104, and the substrate 102.

FIG. 2B is a top view of the integrated circuit 100 of FIG. 2A, in accordance with some embodiments. The top view of FIG. 2B illustrates the fins 112 extending in the X direction and the trenches 110 between the fins 112. The substrate 102 is visible in the trenches 110. The hard mask layer 108 is visible atop the fins 112. FIG. 2B also illustrates cut-lines X and Y. A cross-sectional view along the cut lines Y may be referred to as a “Y-view”. A cross-sectional view along the cut lines X may be referred to as a “X-view”.

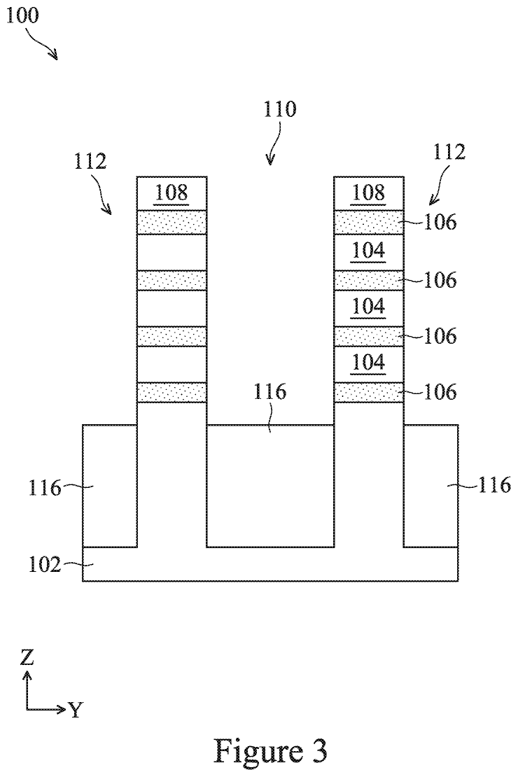

FIG. 3 is a cross-sectional Y-view, in accordance with some embodiments. In FIG. 3, shallow trench isolation regions 116 have been formed by depositing a dielectric material in the trenches 110 between fins 112. The shell dielectric layer may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SiN, SiCN, SiOC, SiOCN, or other dielectric materials without departing from the scope of the present disclosure. After deposition of the dielectric material, an etch-back process has been performed to recess the top of the shallow trench isolation regions 116 below the lowest sacrificial semiconductor layers 106.

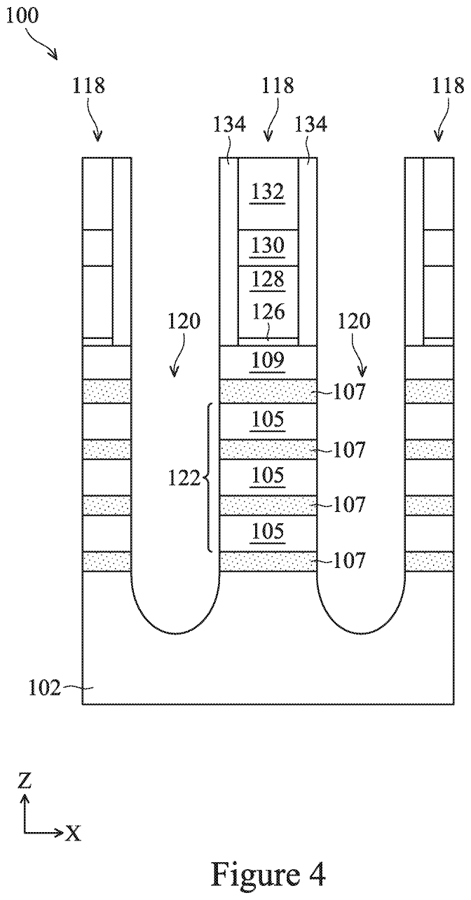

FIG. 4 is an X-view of the integrated circuit 100, in accordance with some embodiments. In FIG. 4, sacrificial gate structures 118 have been formed over the fins 112. The sacrificial gate structures 118 extend in the Y direction, perpendicular to the fins 112. Each sacrificial gate structure 118 crosses multiple fins 112. The sacrificial gate structures 118 are also formed in the trenches 110.

The sacrificial gate structures 118 include a dielectric layer 126. In an exemplary embodiment, the dielectric layer 126 includes silicon oxide. However, alternatively, the dielectric layer 126 can include SiN, SiCN, SiOC, SiOCN, or other dielectric materials without departing from the scope of the present disclosure. In some embodiments, the dielectric layer 126 has a low K dielectric material. The dielectric layer 126 can be deposited by CVD, ALD, or PVD.

The sacrificial gate structures include a sacrificial gate layer 128 on the dielectric layer 126. The sacrificial gate layer 128 can include materials that have a high etch selectivity with respect to the trench isolation regions 116. In an exemplary embodiment, sacrificial gate layer 128 includes polysilicon. However, the sacrificial gate layer 128 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 128 may be deposited by physical vapor deposition (PVD), CVD, sputter deposition, or other techniques for depositing the selected material.

The sacrificial gate structures 118 include a dielectric layer 130 on the sacrificial gate layer 128 and a dielectric layer 132 of the dielectric layer 130. The dielectric layers 130 and 132 may correspond to first and second mask layers. The dielectric layer 130 can include silicon nitride, silicon oxynitride, or other suitable dielectric materials. The dielectric layer 130 can include silicon nitride, silicon oxynitride or other suitable dielectric materials. The dielectric layers 130 and 132 are different materials from each other and can be deposited using CVD, ALD, PVD, or other suitable deposition processes. Other materials and deposition processes can be utilized for the dielectric layers 130 and 132 without departing from the scope of the present disclosure.

Gate spacer layers 134 have been formed on the sidewalls of the layers 126, 128, 130, and 132. The gate spacer layers 134 may also be formed on other exposed surfaces of the integrated circuit. The gate spacer layer 134 can be formed by PVD, CVD, ALD, or other suitable deposition processes. Following formation of the gate spacer layer 134, horizontal portions (e.g., in the X-Y plane) of the gate spacer layer 134 may be removed by an anisotropic etching process, thereby exposing upper surfaces of the fins 112 and the dielectric layer 134. After patterning of the gate spacer layers, vertically thicker portions of the gate spacer layers 134 remain, such as the portion shown in FIG. 4. The gate spacer layers 134 can include one or more of SiO, SiN, SiON, SiCN, SiOCN, SiOC, or other suitable dielectric materials.

After patterning of the gate spacer layers 134, and etching process is performed to etch exposed portions of the hard mask layer 108, resulting in hard mask structures 109 as shown in FIG. 4. In FIG. 2B, the hard mask layer 108 was shown as long unbroken strips on top of the fins 112 extending in the X direction. After patterning of the hard mask layer 108, the long strips of the hard mask layer 108 are broken up to form the smaller hard mask structures 109, as shown in FIG. 4. Accordingly, each strip of the hard mask layer 108 has been patterned to form a plurality of hard mask structures.

In FIG. 4, the hard mask structure 109 is utilized as a mask for forming source/drain trenches 120 in the fins 112. One or more etching processes are performed to form the source/drain trenches 120 in the fins 112. Forming the source/drain trenches 120 includes etching through each of the semiconductor layers 104 and sacrificial semiconductor layers 106, and a portion of the substrate 102. Accordingly, the removal operations may include suitable etch operations for removing materials of the semiconductor layers 104, the sacrificial semiconductor layers 108, the substrate 102. The etching processes can include reactive ion etching (RIE), neutral beam etching (NBE), atomic layer etching (ALE), or the like.

Formation of the source/drain trenches 120 results in formation of a stack 122 of channels 105 of the transistor below the hard mask structure 109. In particular, the portions of the semiconductor layers 104 remaining below the hard mask structure 109 after formation of the source/drain trenches 120 now correspond to channels of a transistor. Formation of the source/drain trenches 120 also results in formation of a plurality of sacrificial semiconductor nanostructures 107 from the sacrificial semiconductor layers 106. After formation of the source/drain trenches 120, the channels 105 may have substantially the same width and length dimensions as the hard mask structure 109.

As set forth previously, patterning of the hard mask layer 108 results in a large number of individual hard mask structures 109. Likewise, a large number of source/drain trenches 120 are formed in the fins 112. A stack 122 of channels 105 is positioned below each hard mask layer 108. Each stack 122 of channels 105 corresponds to the stacked channels 105 of a transistor.

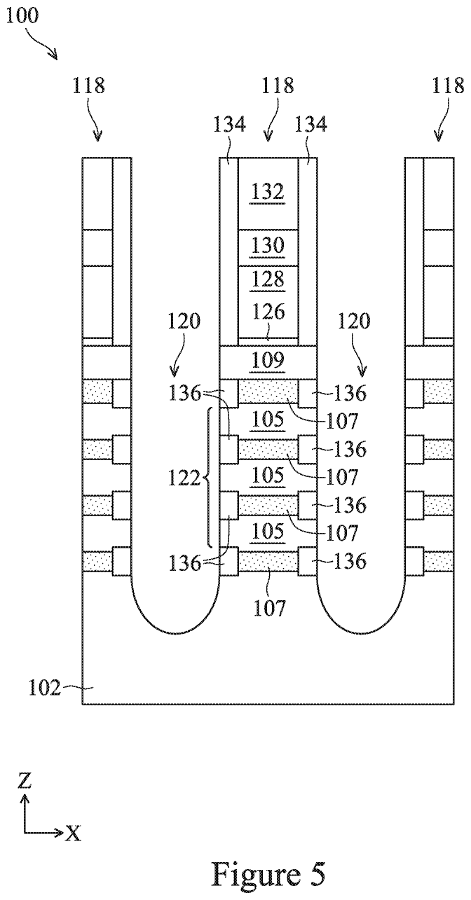

In FIG. 5, inner spacers 136 have been formed. A selective etching process is performed to recess exposed end portions of the sacrificial semiconductor nanostructures 107 without substantially etching the sacrificial semiconductor nanostructures 107. Next, the inner spacers 136 are formed by depositing a dielectric material is deposited to fill the recesses between the channels 105 formed by the previous selective etching process of the sacrificial semiconductor nanostructures 107. The inner spacer 136 may be a suitable dielectric material, such as silicon carbon nitride (SiCN), silicon oxycarbonitride (SiOCN), or the like, formed by a suitable deposition method such as physical vapor deposition (PVD), CVD, ALD, or the like. An etching process, such as an anisotropic etching process, is performed to remove portions of the inner spacer 136 disposed outside the recesses in the sacrificial semiconductor nanostructures 107. The remaining portions of the dielectric layer corresponds to the inner spacers 136 shown in FIG. 5.

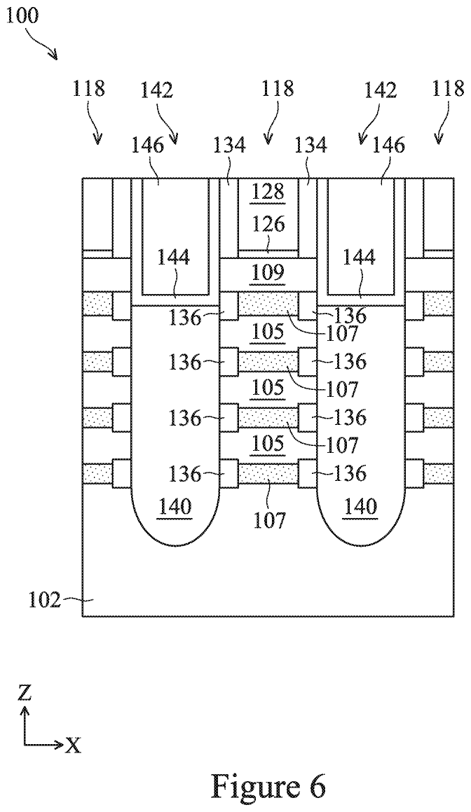

In FIG. 6 source/drain regions 140 have been formed. In the illustrated embodiment, the source/drain regions 140 are epitaxially grown from the channels 105. The source/drain regions 140 are grown on exposed portions of the fins 112 and contact the channels 105. For each stack 122 of channels 105, there are two source/drain regions 140. Some stacks 122 of channels 105 may share a source/drain 140 with a stack 122 of channels 105 that is adjacent in the X direction.

Though not shown, dielectric support elements corresponding to remnants of the gate spacer layers 134 on the trench isolation regions 116 may laterally confine the growth of source/drain regions 140. In some embodiments, the source/drain regions 140 exert stress in the respective channels 105, thereby improving performance. The source/drain regions 140 are formed such that each sacrificial gate structure 118 is disposed between respective neighboring pairs of the source/drain regions 140. In some embodiments, the spacer layer 134 and the inner spacers 136 separate the source/drain regions 140 from the sacrificial gate layer 128 by an appropriate lateral distance (e.g., in the X-axis direction) to prevent electrical bridging to subsequently formed gates of the resulting device.

The source/drain regions 140 may include any acceptable material, such as appropriate for n-type or p-type devices. For n-type devices, the source/drain regions 140 include materials exerting a tensile strain in the channel regions, such as silicon, SiC, SiCP, SiP, or the like, in some embodiments. When p-type devices are formed, the source/drain regions 140 include materials exerting a compressive strain in the channel regions, such as SiGe, SiGeB, Ge, GeSn, or the like, in accordance with certain embodiments. The source/drain regions 140 may have surfaces raised from respective surfaces of the fins and may have facets. Neighboring source/drain regions 140 may merge in some embodiments to form a singular source/drain region 140 over two neighboring fins of the fins 112.

The source/drain regions 140 may be implanted with dopants followed by an annealing process. The source/drain regions 140 may have an impurity concentration of between about 10¹⁹ cm⁻³ and about 10²¹ cm⁻³. N-type and/or p-type impurities for source/drain regions 140 may be any of the impurities previously discussed. In some embodiments, the source/drain regions 140 are in situ doped during growth.

In FIG. 6, a contact etch stop layer (CESL) 144 and an interlayer dielectric (ILD) 146 have been formed. The CESL layer 144 can include a thin dielectric layer can formally deposited on exposed surfaces of the source/drain regions 140 and on other exposed surfaces. The CESL layer 144 can include SiN, SiC, SiOC, SiOCN, SiON, or other suitable dielectric materials. The CESL 144 can be deposited by CVD, ALD, PVD, or other suitable deposition processes.

The dielectric layer 146 covers the CESL 144. The dielectric layer 146 can include SiO, SiON, SiN, SiC, SiOC, SiOCN, SiON, or other suitable dielectric materials. The dielectric layer 146 can be deposited by CVD, ALD, PVD, or other suitable deposition processes.

In FIG. 6, a CMP process has been performed to reduce the height of the sacrificial gate structures 118. The results of the CMP process is that the dielectric layers 130 and 132 are entirely removed. The heights of the sacrificial gate layer 128, the gate spacer layers 134, the CESL layer 144, and the dielectric layer 146 have been reduced and the top surfaces have been planarized.

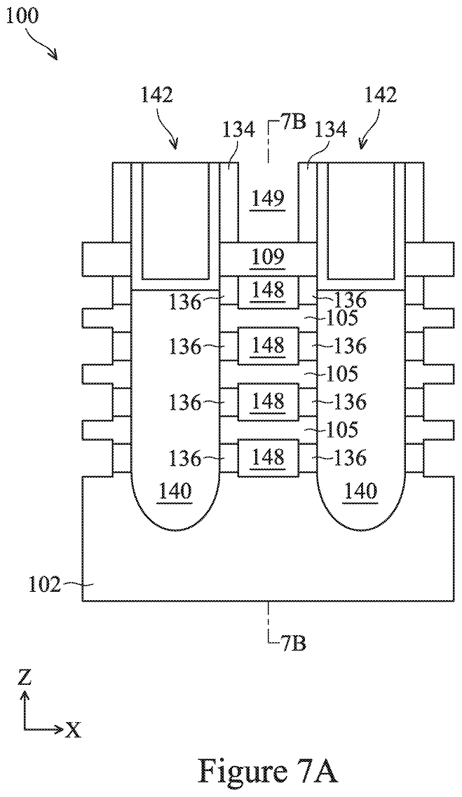

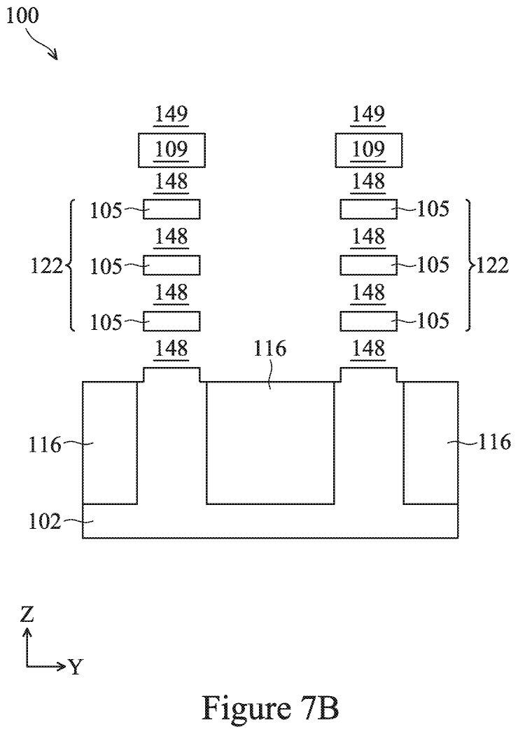

FIG. 7A is an X view of the integrated circuit 100, in accordance with some embodiments. In FIG. 7A, the sacrificial gate structures 118 have been removed from between the gate spacer layers 134. In particular, the dielectric layer 126 and the sacrificial gate layer 128 has been entirely removed from between the gate spacer layers 134.

In some embodiments, the sacrificial gate layer 128 is removed by an anisotropic dry etch process. For example, the etching process may include a dry etch process using reaction gases that selectively etch the sacrificial gate layer 128 without etching the spacer layer 134. The dielectric layer 126, when present, may be used as an etch stop layer when the sacrificial gate layer 128 is etched. The dielectric layer 126 may then be removed after the removal of the sacrificial gate layer 128.

Removal of the sacrificial gate layer 128 and the dielectric layer 126 results in the formation of a void 149 between the gate spacer layers 134 above the channels 105. As will be set forth in more detail below, an upper portion of a gate metal or gate electrode will be formed in the void 149. Accordingly, the sacrificial gate layer 128 is sacrificial in the sense that the upper portion of the gate metal will eventually be formed in its place.

In FIG. 7A, channels 105 are released by removal of the sacrificial semiconductor nanostructures 107. The sacrificial semiconductor nanostructures 107 can be removed by a selective etching process using an etchant that is selective to the material of the sacrificial semiconductor nanostructures 107, such that the sacrificial semiconductor nanostructures 107 are removed without substantially etching the channels 105. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In some embodiments, the sacrificial semiconductor nanostructures 107 are removed and the channels 105 are patterned to form channel regions of both PFETs and NFETs. Removal of the sacrificial semiconductor nanostructures 107 results in the formation of voids 148 between the channels 105.

FIG. 7B is a Y-view of the integrated circuit 100 taken along cut lines 7B in FIG. 7A, in accordance with some embodiments. The view of FIG. 7B illustrates two stacks 122 of channels 105 adjacent to each other in the Y direction. The stack 122 on the left may correspond to the center stack 122 of FIG. 7A.

FIG. 7B illustrates that, while the etching process selectively etches the sacrificial semiconductor nanostructures 107, the channels 105 may also be etched to a relatively small extent. Prior to the etching process that removed the sacrificial semiconductor nanostructures 107, the channels 105 each have a width dimension in the Y direction substantially equal to the width of the corresponding hard mask structure 109. After the removal of the sacrificial semiconductor nanostructures 107, the widths of the channels 105 are reduced. This can have a negative impact on the performance of the transistor that will be formed with the stack 122 of channels 105. In particular, the current in a transistor channel in the on condition is proportional to the width to length ratio of the channel. The length L corresponds to the length in the X direction between adjacent source/drain regions 140. The width W corresponds to the lateral width of the channel in the Y direction. Accordingly, reduction of the width of a channel reduces the current that will be conducted in the on state of the transistor. As will be set forth in more detail below, embodiments of the present disclosure augment the width of the channels 105 after removal of the sacrificial semiconductor nanostructures 107.

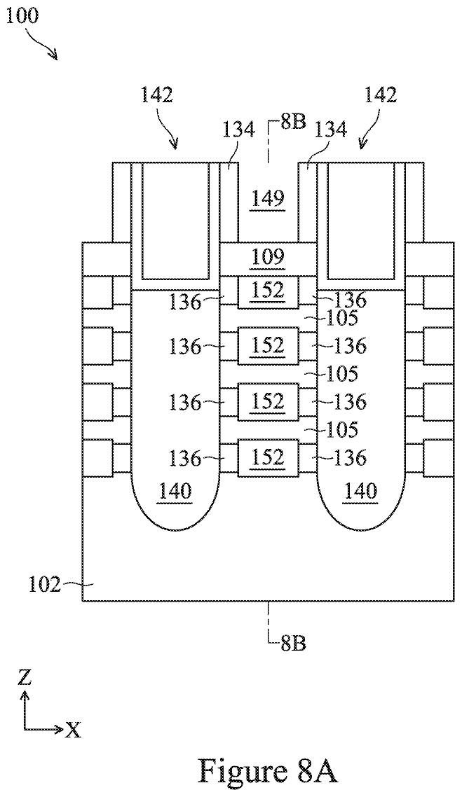

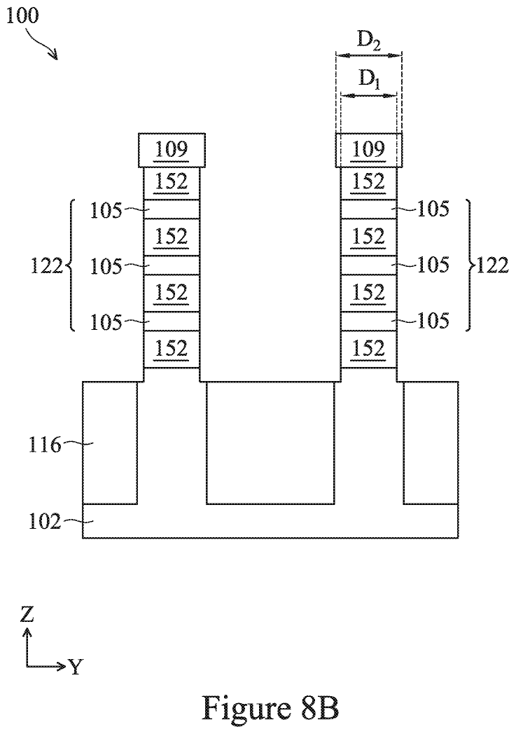

FIG. 8A is an X view of the integrated circuit 100, in accordance with some embodiments. In FIG. 8A, dielectric plugs 152 have been formed in the voids 148 between channels 105, as well as between the highest channel 105 and the hard mask structure 109. The dielectric plugs can include SiN, SiCN, AlO, or other suitable dielectric materials. In some embodiments, the material of the dielectric plugs 109 is selected to be selectively etchable with respect to the hard mask structure 109 and the inner spacers 136. The dielectric plugs 136 can be formed by CVD, ALD, PVD, or other suitable deposition processes. After deposition of the material for the dielectric plugs 136, an etchback process can be performed to remove the dielectric material above the hard mask structure 109. The etchback process also removes the dielectric material that is not directly below the hard mask structures 109.

FIG. 8B is a Y-view of the integrated circuit 100, taken along cut lines 8B in FIG. 8A, in accordance with some embodiments. FIG. 8B illustrates the positions of the dielectric plugs 152. Figure B also illustrates that the dielectric plugs 152 have a substantially equal with in the Y direction as the channels 105. FIG. 8B illustrates that at the stage of processing, the channels 105 have a width dimension D1. The hard mask structures 109 have a width dimension D2. The width dimension D2 is greater than the width dimension D1. In some embodiments, the dimension D2 is between 8 nm and 12 nm. In one example, the width dimension D2 is about 10 nm. The width dimension D2 also corresponds to the width of the protruding portion of the substrate 102. In some embodiments, the width dimension D1 is less than the width dimension D2 by an amount between 0.1 nm and 5 nm, though other dimensions can be utilized without departing from the scope of the present disclosure.

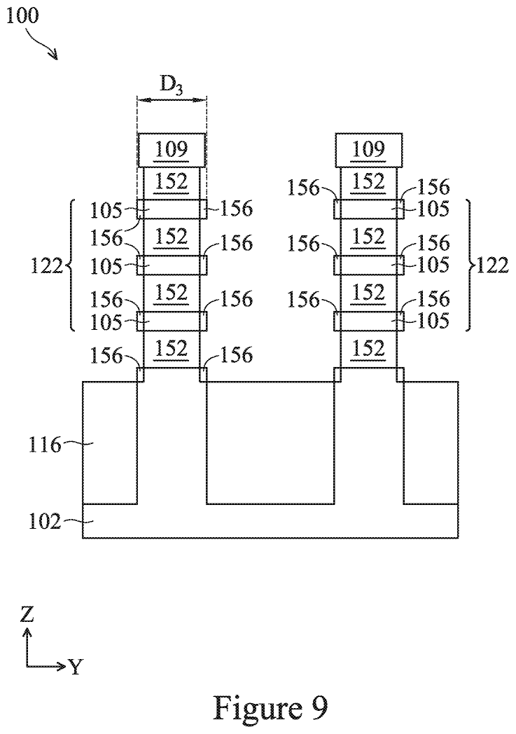

FIG. 9 is a Y-view of the integrated circuit 100, in accordance with some embodiments. In FIG. 9, an epitaxial growth process has been performed. The epitaxial growth process causes an epitaxial semiconductor layer 156 to form on the sides of each channel 105. In particular, the epitaxial semiconductor layer 156 grows on the exposed left and right sides of the channels 105, in the Y direction. The epitaxial semiconductor layer 156 is a semiconductor material. The epitaxial semiconductor layer 156 can be a monocrystalline semiconductor layer growing from the crystal lattice structure of the channel 105. In some embodiments, the epitaxial layer 156 can be a semiconductor having different composition or different crystal lattice structure that the channels 105. In some embodiments, the epitaxial semiconductor layer 156 can have a same composition and or crystal lattice structure as the channels 105. In some embodiments, and interface is formed between the epitaxial semiconductor layer 156 and the channels 105.

In one example, the channels 105 are intrinsic semiconductor material. The epitaxial semiconductor layers 156 can also be an intrinsic semiconductor material. The epitaxial semiconductor layers 156 can be a same material as the channels 105. In some embodiments, the epitaxial semiconductor layers 156 may be lightly doped with dopant species.

After the epitaxial growth process to form the epitaxial semiconductor layers 156, the effective width of the channels 105 has increased. The width of the channels 105 now corresponds to the width dimension D3 between an end of the semiconductor layer on one side of the channel 105 and the end of the semiconductor layer on the other side of the channel 105 in the Y direction. In some embodiments, the dimension D3 is larger than the dimension D2 shown in FIG. 8B. In some embodiments, the dimension D3 is larger than the dimension D2 by an amount between 0.1 nm and 5 nm.

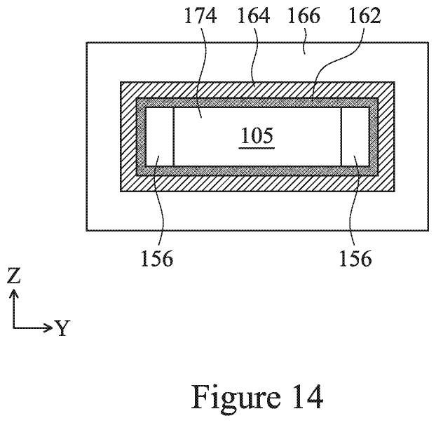

FIG. 9 illustrates that the epitaxial semiconductor layers 156 are substantially rectangular in cross-section. However, in practice, the epitaxial semiconductor layers 156 may have curved surfaces. In some embodiments, the epitaxial semiconductor layers 156 grown both upward and outward from the channels 105. The result is that the channels 105 have a dumbbell shape after formation of the epitaxial semiconductor layers 156. Further details regarding the shape of the epitaxial semiconductor layers 156 can be seen in relation to the enlarged views of FIGS. 14, 15, and 16, described further below.

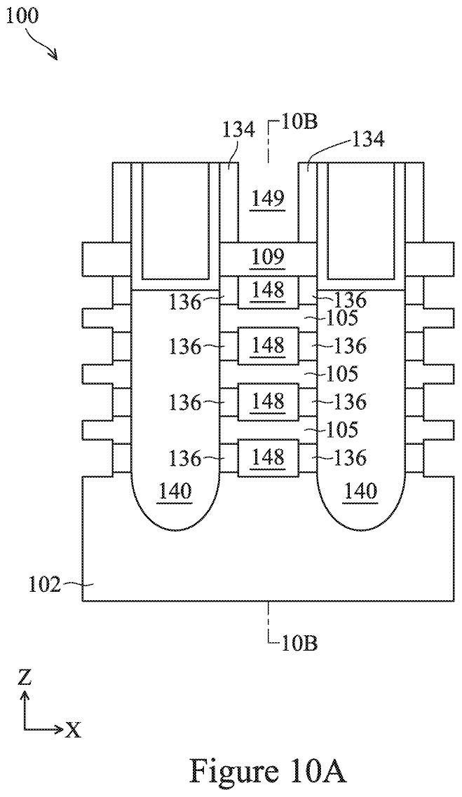

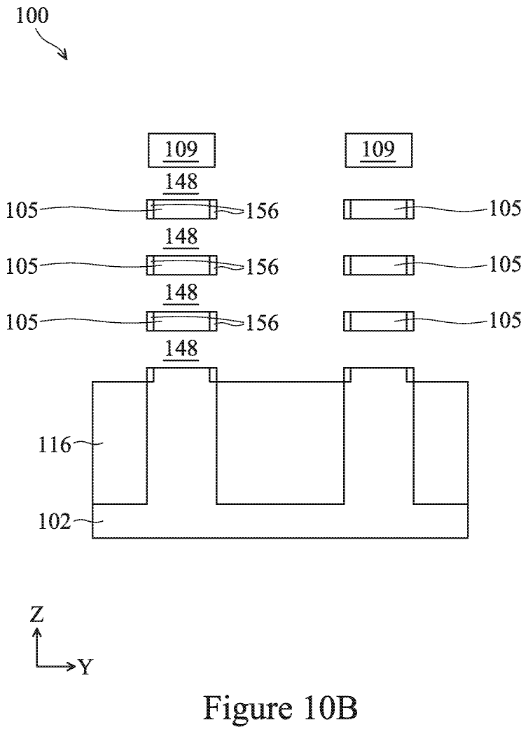

FIG. 10A is an X view of the integrated circuit 100, in accordance with some embodiments. In FIG. 10A, the dielectric plugs 156 have been removed. The dielectric plugs 156 can be removed by an etching process that selectively etches the material of the dielectric plugs 156 with respect to the dielectric materials of the hard mask structure 109 and the inner spacers 136. Removal of the dielectric plugs 156 results in formation or return of the voids 148.

FIG. 10B is a Y-view of the integrated circuit 100 of FIG. 10B, in accordance with some embodiments. FIG. 10B illustrates the voids 148 formed between the channels 105.

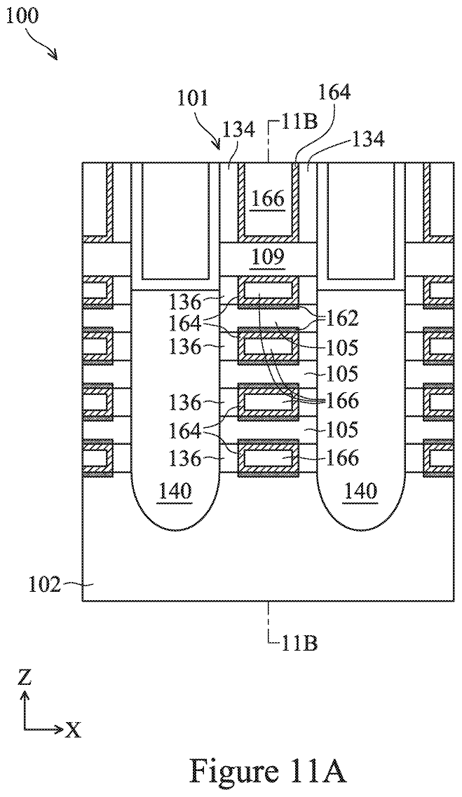

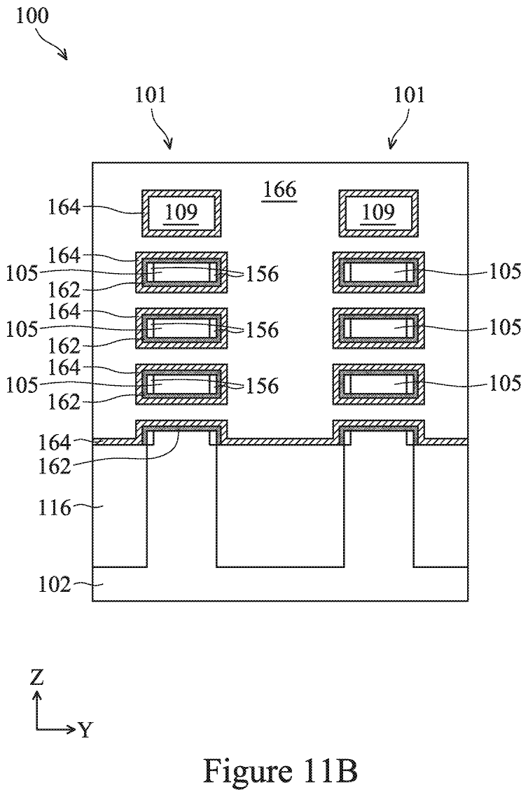

FIG. 11A is an X view of the integrated circuit 100, in accordance with some embodiments. FIG. 11B is a Y-view of the integrated circuit 100 taken along cut lines 11B in FIG. 11A, in accordance with some embodiments. With reference to FIGS. 11A and 11B, an interfacial gate dielectric layer 162 has been deposited. The interfacial gate dielectric layer 162 is deposited on all exposed surfaces of the channels 105. The interfacial gate dielectric layer 162 is wrapped around the channels 105. The interfacial gate dielectric layer 162 can include a dielectric material such as silicon oxide, silicon nitride, or other suitable dielectric materials. The interfacial gate dielectric layer 162 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 162 can be formed by a thermal oxidation process, a chemical vapor deposition (CVD) process, or an atomic layer deposition (ALD) process. The interfacial gate dielectric layer 162 can have a thickness between 0.5 nm and 2 nm. Other materials, deposition processes, and thicknesses can be utilized for the interfacial gate dielectric layer 162 without departing from the scope of the present disclosure.

A high-K dielectric layer 164 has been deposited. The high-K dielectric layer 164 is deposited in a conformal deposition process. The conformal deposition process deposits the high-K dielectric layer 164 on the interfacial gate dielectric layer 162, on the hard mask structure 109, on the substrate 102, on the trench isolation regions 116, and on the gate spacer layers 134. The high-K gate dielectric layer 164 is wrapped around the channels 105. The high-K gate dielectric layer 164 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer 164 may be formed by CVD, ALD, or any suitable method. Other thicknesses, deposition processes, and materials can be utilized for the high-K dielectric layer 164 without departing from the scope of the present disclosure.

A gate metal 166 has been deposited. The gate metal 166 is deposited on all exposed surfaces of the high-K dielectric layer 164. The gate metal 166 is wrapped around the channels 105. The gate metal 166 is also wrapped around the hard mask structures 109 such that the gate metal 166 is positioned between the highest channel 105 and the hard mask structure 109. Although the gate metal 166 is shown as a single layer in FIGS. 11A and 11B, in practice, the gate metal 166 can include one or more conductive liner layers, work function layers, and gate fill layers that collectively make up the gate metal. The gate metal can include one or more of Ti, TiN, Ta, TaN, Al, Cu, Co, Ru, W, Au, or other suitable conductive materials. The gate metal 166 can be deposited by PVD, ALD, or CVD. Other configurations, materials, and deposition processes can be utilized for the gate metal 166 without departing from the scope of the present disclosure.

At the stage of processing shown in FIGS. 11A and 11B, the transistors 101 are substantially complete. Each transistor 101 includes a stack 122 of channels 105 extending between the source/drain regions 140 and acting as stacked channels of the transistor 101. The gate metal 166 acts as a gate electrode surrounding the channels 105.

In FIG. 11B, there are no breaks in the gate metal 166, such that the gate electrodes of adjacent transistors 101 are all shorted together. Though not shown in FIG. 11B, in further processing steps cut-gate processes may be performed to electrically isolate portions of the gate metal 166 to form electrically isolated gate electrodes for the transistors 101.

Though not shown in FIGS. 11A and 11B, source/drain contacts may also be formed. Trenches can be formed in the dielectric layers 144 and 146 to expose the top surfaces of the source/drain regions 140. A silicide may be formed on the exposed portions of the source/drain regions 140. The conductive via or plug can be formed in contact with the silicide. The voltages can be applied to source/drain regions, or currents can be passed via the source/drain contacts.

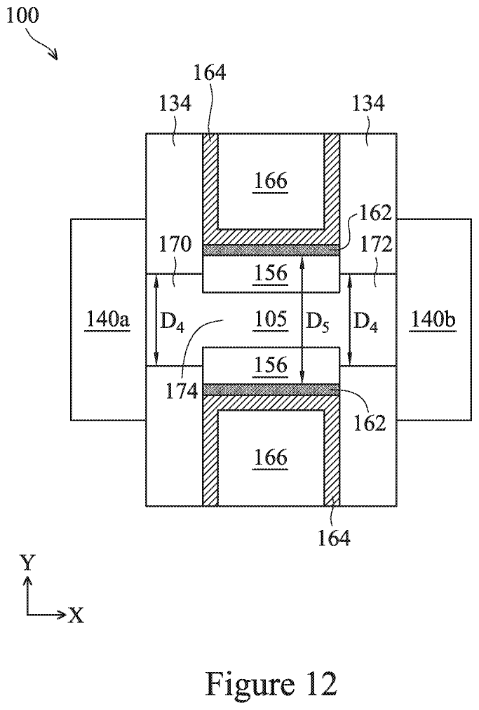

FIG. 12 is an enlarged cross-sectional view of a portion of a transistor 101, in accordance with some embodiments. The top sectional view is taken as an X-Y plane through one of the channels 105 of the transistor 101. FIG. 12 illustrates that the channel 105 has a first end 170 coupled to a first source/drain region 140a. The channel 105 has a second end 172 coupled to a second source/drain region 140b. The ends 170 and 172 each have a same width dimension D4 in the Y direction. The end regions 170 and 172 are bounded by the gate spacer layers 134. FIG. 12 also illustrates that the channel 105 has a middle portion or middle region 174 between the end 170 and the end 172. The middle portion 174 includes the epitaxial semiconductor layers 156. The epitaxial semiconductor layers 156 are in contact with the interfacial dielectric layer 162. The epitaxial semiconductor layers 156 results in the middle portion 174 having a width dimension D5 (corresponding to the width dimension D3). The width dimension D5 is greater than the width dimension D4, as described previously.

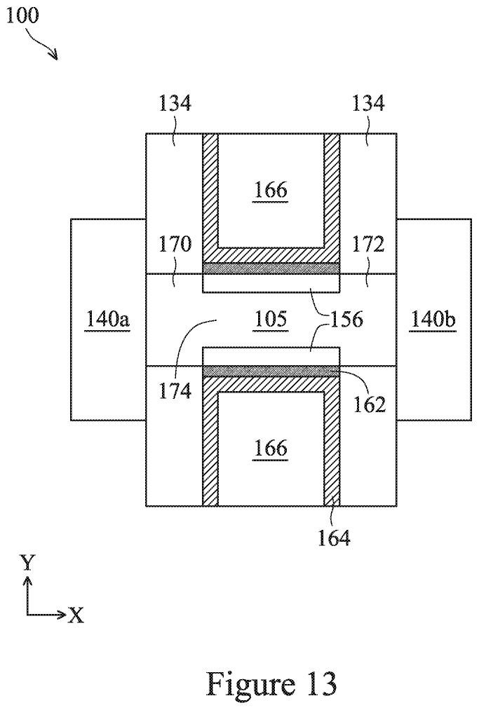

FIG. 13 is an enlarged cross-sectional view of a portion of a transistor 101, in accordance with some embodiments. The top sectional view is taken as an X-Y plane through one of the channels 105 of the transistor 101. In the example of FIG. 13, the middle portion 174 has a width dimension that is substantially the same as the width dimensions of the ends 170 and 172. This can result from controlling the epitaxial growth process that forms the epitaxial semiconductor layers 156 in a manner that results in the middle portion 174 having substantially the same width as the ends 170 and 172.

FIG. 14 is an enlarged cross-sectional view of a channel 105 of a transistor 101, in accordance with some embodiments. The cross-section is taken in the middle portion 174 of the channel 105. The cross-sectional view of FIG. 14 illustrates that epitaxial semiconductor layers 156 have a substantially rectangular cross-section. This results in an overall rectangular cross-section of the channel 105. The view of FIG. 14 illustrates the interfacial dielectric layer 162 in contact with the channel 105, the high K dielectric layer 164 in contact with the interfacial dielectric layer 162, and the gate metal 166 in contact with the high K dielectric layer 164.

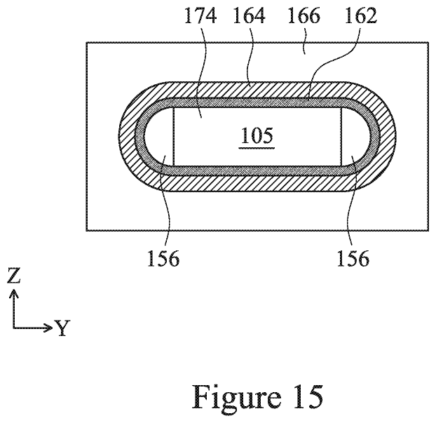

FIG. 15 is an enlarged cross-sectional view of a channel 105 of a transistor 101, in accordance with some embodiments. The cross-section is taken in the middle portion 174 of the channel 105. The cross-sectional view of FIG. 15 illustrates that epitaxial semiconductor layers 156 have curved surfaces. The view of FIG. 15 illustrates the interfacial dielectric layer 162 in contact with the channel 105, the high K dielectric layer 164 in contact with the interfacial dielectric layer 162, and the gate metal 166 in contact with the high K dielectric layer 164.

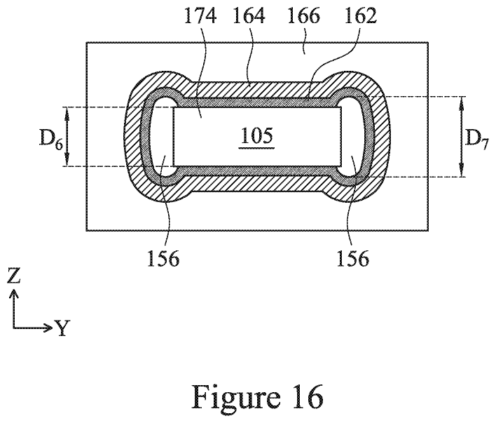

FIG. 16 is an enlarged cross-sectional view of a channel 105 of a transistor 101, in accordance with some embodiments. The cross-section is taken in the middle portion 174 of the channel 105. The cross-sectional view of FIG. 14 illustrates that epitaxial semiconductor layers 156 have grown both in the Z direction and the Y direction from the channels 105. This results in an overall dumbbell shape or cross-section of the channel 105. The central portion of the channel 105 has a height dimension D6, while the epitaxial semiconductor layers 156 have a height dimension D7. D7 is greater than D6. In some embodiments, D6 is between 0.5 nm and 4 nm. In some embodiments, D7 is between 0.8 nm and 7 nm. Other dimensions can be utilized without departing from the scope of the present disclosure. The view of FIG. 15 illustrates the interfacial dielectric layer 162 in contact with the channel 105, the high K dielectric layer 164 in contact with the interfacial dielectric layer 162, and the gate metal 166 in contact with the high K dielectric layer 164.

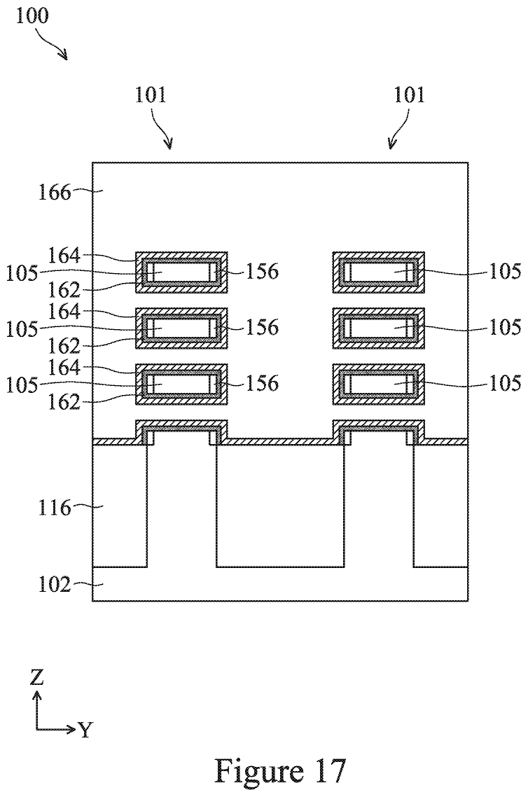

FIG. 17 is a cross-sectional view of an integrated circuit 100, in accordance with some embodiments. The view of FIG. 17 is substantially similar to the view of FIG. 11B, except that the hard mask structures 109 have been removed. In particular, the hard mask structures 109 are removed after formation of the epitaxial semiconductor layers 156 and prior to formation of the interfacial dielectric layer 162. The hard mask structures 109 can be removed via an etching process that selectively etches the hard nanostructures 109 with respect to other exposed materials. The result is that there is no hard mask structure 109 present above the channels 105. This can result in an overall higher conductivity of the gate metal 166.

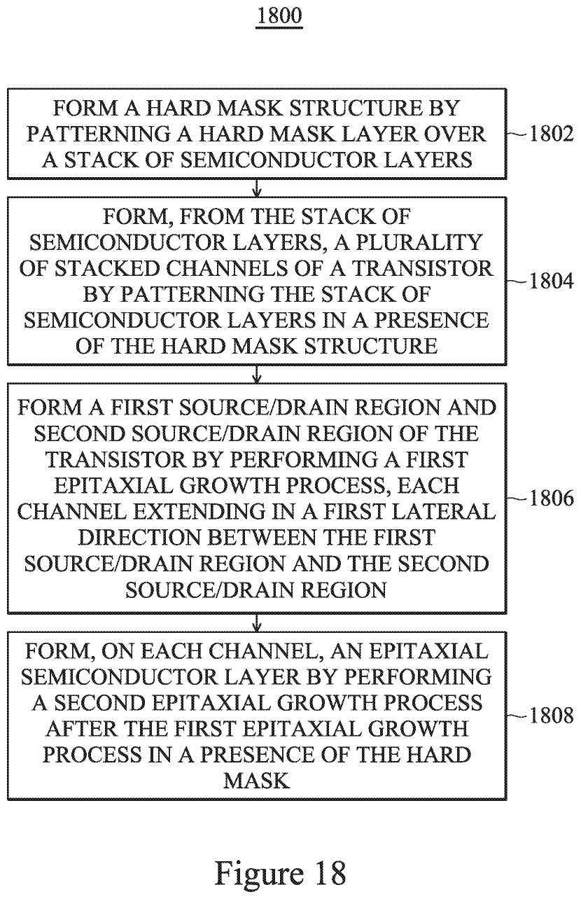

FIG. 18 is a flow diagram of a method 1800 for forming an integrated circuit, in accordance with some embodiments. The method 1800 can utilize the structures, processes, and systems described in relation to FIGS. 1-17. At 1802, the method 1800 includes forming a hard mask structure by patterning a hard mask layer over a stack of semiconductor layers. One example of a stack of semiconductor layers is the stack 103 of semiconductor layers of FIG. 1. One example of a hard mask structure is the hard mask structure 109 of FIG. 4. At 1804, the method 1800 includes forming, from the stack of semiconductor layers, a plurality of stacked channels of a transistor by patterning the stack of semiconductor layers in a presence of the hard mask structure. One example of stacked channels are the stacked channels 105 of FIG. 4. At 1806, the method 1800 includes forming a first source/drain region and a second source/drain region of the transistor by performing a first epitaxial growth process, each channel extending in a first lateral direction between the first source/drain region and the second source/drain region. One example of source/drain regions are the source/drain regions 140 of FIG. 6. At 1808, the method 1800 includes forming, on each channel, an epitaxial semiconductor layer by performing a second epitaxial growth process after the first epitaxial growth process in a presence of the hard mask. One example of an epitaxial semiconductor layer is the epitaxial semiconductor layer 156 of FIG. 9.

Embodiments of the disclosure provide a gate all around transistor including a plurality of stacked channels. Embodiments of the present disclosure utilize a hard mask structure to assist in patterning the channels from a plurality of semiconductor layers. After formation of source/drain regions of the transistor, an epitaxial growth process is performed to effectively increase the channel width of each of the channels by forming an epitaxial semiconductor layer on the exposed side surfaces of the channels. Prior to the epitaxial growth process, the channels may have a width that is slightly smaller than a width of the hard mask structure. After the epitaxial growth process, the channels may have a width that is larger than the width of the hard mask structure. The result is a transistor with increased effective channel width. This results in increased currents in the on state of the transistor in the overall better performance of the transistor and electronic devices that incorporate the integrated circuit in which the transistor is formed.

In some embodiments, a device includes a transistor. The transistor includes a first source/drain region, a second source/drain region, and a plurality of stacked channels each extending in a first lateral direction between the first source/drain region and the second source/drain region and having a first width in a second lateral direction. The transistor includes a hard mask structure directly above the stacked channels and having a second width in the second direction smaller than the first width.

In some embodiments, a device includes a transistor. The transistor includes a first source/drain region, a second source/drain region, and a plurality of stacked channels each extending in a first lateral direction between the first source/drain region and the second source/drain region and having a first end region adjacent to the first source/drain region, a second end region adjacent to the second source/drain region, and a middle region between the first and second end regions. The the first and second end regions each have a first width in a second lateral direction transverse to the first lateral direction. The middle region has a second width larger than the first width in the second lateral direction.

In some embodiments, a method includes forming a hard mask structure by patterning a hard mask layer over a stack of semiconductor layers and forming, from the stack of semiconductor layers, a plurality of stacked channels of a transistor by patterning the stack of semiconductor layers in a presence of the hard mask structure. The method includes forming a first source/drain region and a second source/drain region of the transistor by performing a first epitaxial growth process. Each channel extends in a first lateral direction between the first source/drain region and the second source/drain region. The method includes forming, on each channel, an epitaxial semiconductor layer by performing a second epitaxial growth process after the first epitaxial growth process in a presence of the hard mask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of stacked channels of a transistor by etching a plurality of semiconductor layers in a presence of a hard mask structure;
extending a width of the channels relative to a width of the hard mask structure by performing an epitaxial growth process in the presence of the hard mask structure;
forming a first source/drain region and a second source/drain region of the transistor after extending the width of the channels, the channels extending lengthwise between the first source/drain region and the second source/drain region.

2. The method of claim 1, wherein the hard mask structure and the channels each have a same length.

3. The method of claim 1, further comprising depositing a gate electrode wrapped around each of the channels and the hard mask structure.

4. The method of claim 1, further comprising depositing a gate electrode wrapped around each of the channels after removing the hard mask structure.

5. The method of claim 4, wherein the epitaxial growth process produces on the channels an epitaxial semiconductor layer of a different material than the first source/drain region.

6. The method of claim 4, wherein the epitaxial semiconductor layer is an intrinsic semiconductor material.

7. The method of claim 4, wherein each channel has a dumbbell shape.

8. The method of claim 4, wherein the epitaxial semiconductor layer is rounded.

9. The method of claim 1, further comprising depositing a gate dielectric layer wrapped around each of the channels and the hard mask structure, wherein the gate dielectric is positioned between each channel and a gate metal, wherein the gate dielectric is positioned between the hard mask structure and the gate metal.

10. The method of claim 1, wherein a bottom surface of the hard mask structure is higher than a top surface of the first source/drain region.

11. A device, comprising:
a transistor including:
a first source/drain region;
a second source/drain region; and
a plurality of stacked channels each extending in a first lateral direction between the first source/drain region and the second source/drain region;
a hard mask structure above the channels, wherein the channels are wider in a second lateral direction than the hard mask structure.

12. The device of claim 11, wherein each channel has a first end region adjacent to the first source/drain region, a second end region adjacent to the second source/drain region, and a middle region between the first and second end regions, wherein the first and second end regions each have a first width in the second lateral direction, wherein the middle region has a second width larger than the first width in the second lateral direction.

13. The device of claim 12, wherein the hard mask structure has a uniform width in the second lateral direction equal to the first width and a length in the first lateral direction equal to a length of each of the channels.

14. The device of claim 13, wherein the transistor includes a gate metal wrapped around each of the channels and the hard mask structure.

15. The device of claim 13, wherein the transistor includes:
a gate dielectric layer in contact with the middle region of each channel but not in contact with the first and second end regions of each channel; and
a metal wrapped around the middle region of each channel.

16. The device of claim 13, wherein the middle region of each channel includes an epitaxial semiconductor layer in contact with the gate dielectric.

17. A method, comprising:
forming a hard mask structure by patterning a hard mask layer over a stack of semiconductor layers;
forming, from the stack of semiconductor layers, a plurality of stacked channels of a transistor by patterning the stack of semiconductor layers;
forming a first source/drain region and a second source/drain region of the transistor by performing a first epitaxial growth process, each channel extending lengthwise in a first lateral direction between the first source/drain region and the second source/drain region; and
increasing a width of each channel in a second lateral direction by forming, on each channel, an epitaxial semiconductor layer by performing a second epitaxial growth process after the first epitaxial growth process.

18. The method of claim 17, comprising:
removing the hard mask structure; and
forming a gate metal wrapped around each of the channels after removing the hard mask structure.

19. The method of claim 17, comprising forming a gate metal of the transistor wrapped around each of the channels and the hard mask structure.

20. The method of claim 17, wherein after the second epitaxial growth process the channels a middle portion of each channel is wider in a second lateral direction transverse to the first lateral direction than are first and second portions of each channel, the first end portion adjacent to the first source/drain region, the second end portion adjacent to the second source/drain region.
